(19) United States
(12) Patent Application Publication
(10) Pub. No.: US 2010/0297854 A1
(43) Pub. Date: Nov. 25, 2010

(54) HIGH THROUGHPUT SELECTIVE OXIDATION OF SILICON AND POLYSILICON USING PLASMA AT ROOM TEMPERATURE

(75) Inventors: Sundar Ramamurthy, Fremont, CA (US); Majeed Foad, Sunnyvale, CA (US); Matthew Scotney-Castle, Morgan Hill, CA (US); Marla Britt, Campbell, CA (US); Yen B. Ta, Pomona, CA (US)

Correspondence Address: MOSER IP LAW GROUP / APPLIED MATERIALS, INC., 1030 BROAD STREET, SUITE 203, SHREWSBURY, NJ, 07702, US

(73) Assignee: APPLIED MATERIALS, INC., Santa Clara, CA (US)

(21) Appl. No.: 12/763,653

(22) Filed: Apr. 20, 2010

Related U.S. Application Data
(60) Provisional application No. 61/171,506, filed on Apr. 22, 2009.

(51) Int. Cl. H01L 21/31

(52) U.S. Cl. 438/788; 257/E21.24

(57) ABSTRACT

Methods of fabricating an oxide layer on a semiconductor structure are provided herein. In some embodiments, a method of selectively forming an oxide layer on a semiconductor structure includes providing a substrate having one or more metal-containing layers and one or more non metal-containing layers to a substrate support in a plasma reactor; introducing a first process gas into the plasma reactor, wherein the first process gas comprises hydrogen (H₂) and oxygen (O₂); maintaining the structure at a temperature of less than about 100 degrees Celsius; and generating a first plasma from the first process gas to selectively form an oxide layer on the one or more non metal-containing layers, wherein the first plasma has a density of greater than about 10¹⁰ ions/cm³.

### CROSS-REFERENCE TO RELATED APPLICATIONS

This application claims benefit of U.S. provisional patent application Ser. No. 61/171,506, filed Apr. 22, 2009, which is herein incorporated by reference in its entirety.

### FIELD

Embodiments of the present invention generally relate to semiconductor fabrication, and more particularly, to oxidation of a semiconductor device or its components.

### BACKGROUND

Semiconductor devices require thin oxide layers to be formed at various stages of their fabrication. For example, in transistors, a thin gate oxide layer may be formed as part of a gate stack structure. In addition, in some applications, such as in the fabrication of a flash memory film stack, a thin oxide layer may be formed surrounding the entire gate stack (referred to herein as pure oxidation), for example, via exposing the stack to an oxidation process. Such oxidation processes have conventionally been performed either thermally or using a plasma. In other applications, the oxide layer may be only formed on certain layers of a film stack (referred to herein a selective oxidation).

Thermal processes for forming oxide layers, for example, the gate oxide layer or the gate stack oxide layer, have worked relatively well in fabrication of semiconductor devices of the larger feature sizes used in the past. Unfortunately, as feature sizes are becoming much smaller and different oxides are employed in the next generation of advanced technologies, the high wafer temperatures required in thermal oxidation processes are problematic in that the sharp junction definitions which are now required become diffused at the higher temperatures (e.g., above about 700 degrees Celsius). Such a distortion of junction definitions and other features can lead to poor device performance or failure.

Plasma processes used to form oxide layers have similar problems. For example, at high chamber pressure (e.g., 100 mTorr), contaminants tend to accumulate in the gate oxide layer during formation, leading to fatal defects in the gate oxide structure such as dangling bonds or mobile charge, and at low chamber pressure (e.g., tens of mTorr), increased plasma ion energy leads to ion bombardment damage and other diffusion problems.

For example, conventional oxidation processes often result in a defect known as a bird's beak. Bird's beak refers to diffusion of the oxide layer into the layers of the film stack structure from the sides at the interface between adjacent layers, rounding off the corners of the adjacent layers. The resultant defect has a profile that resembles a bird's beak. The intrusion of the oxide layer into the active region of the memory cell (e.g., in flash memory applications) reduces the active width of the memory cell, thereby undesirably reducing the effective width of the cell and degrading the performance of the flash memory device.

In some film stack structures comprising both metal and non-metal containing layers, such as in DRAM memory devices, sidewall oxidation of the non-metal containing layers is desired with the limitations described above. Oxidation of the metal containing layers, however, limits electrical conductivity and reduces device function. There is a need for an improved method which both limits defects such as bird's beak in non metal containing layers on which an oxide layer is formed, and selectively form an oxide layer on only the non metal containing layers.

Thus, there is a need for improved methods for oxidizing film stack structures.

### SUMMARY

Methods of fabricating an oxide layer on a semiconductor structure are provided herein. In some embodiments, a method of selectively forming an oxide layer on a semiconductor structure includes providing a substrate having one or more metal-containing layers and one or more non metal-containing layers to a substrate support in a plasma reactor; introducing a first process gas into the plasma reactor, wherein the first process gas comprises hydrogen (H₂) and oxygen (O₂); maintaining the structure at a temperature of less than about 100 degrees Celsius; and generating a first plasma from the first process gas to selectively form an oxide layer on the one or more non metal-containing layers, wherein the first plasma has a density of greater than about 10¹⁰ ions/cm³.

In some embodiments, the method may further comprise introducing a second process gas into the plasma reactor, wherein the second process gas comprises hydrogen (H₂); and generating a second plasma from the second process gas, wherein the second plasma has a plasma density greater than about ions/cm³. In some embodiments, the first and second plasmas are provided to the structure in an iterative sequence.

In some embodiments, the temperature of the substrate is maintained at a temperature of between about 25-75 degrees Celsius. In some embodiments, the temperature is maintained at room temperature (about 22.5 degrees Celsius, or between about 20 to about 25 degrees Celsius).

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of an oxidation process in accordance with some embodiments of the present invention.

FIGS. 2A-B illustrate stages of fabrication of a semiconductor structure in accordance with some embodiments of the present invention.

FIG. 3 illustrates a plasma reactor suitable for carrying out embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods for oxidation of semiconductor structure. The inventive processes advantageously provide selective formation of the oxide layer on selected layers of a semiconductor structure (selective oxidation) at low temperatures, thereby facilitating increased throughput as compared to high temperature oxidation processes. In addition, the process disclosed herein may facilitate improved growth rate and selectivity of the oxide layer at a reduced thermal budget, thereby limiting diffusion effects by reducing the exposure time of the substrate to the process as compared to conventional oxidation processes.

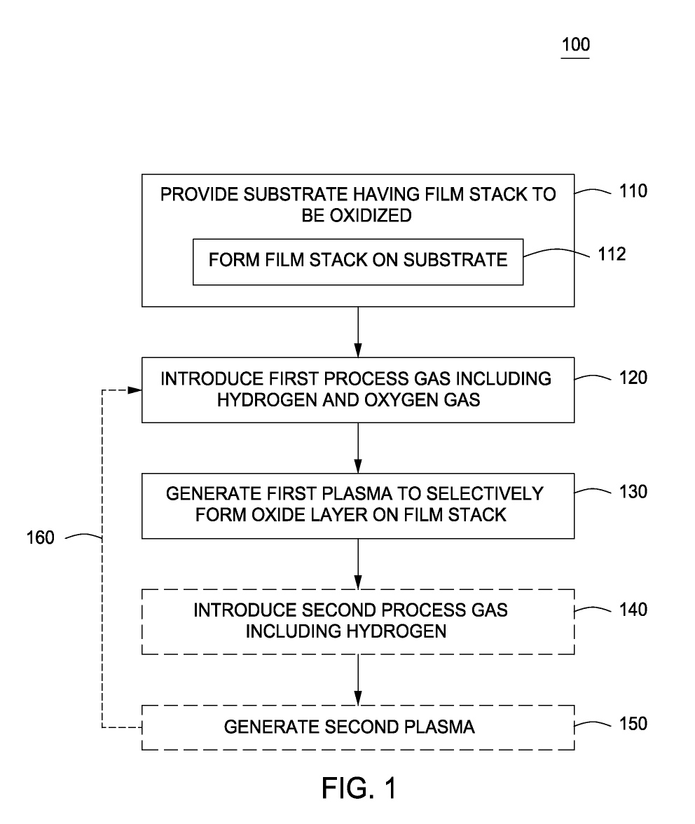

FIG. 1 depicts an illustrative process 100 for forming an oxide layer in accordance with some embodiments of the present invention. Generally, the process 100 includes providing a semiconductor structure including a substrate having a film stack disposed thereon. The semiconductor structure may be a partially fabricated semiconductor device such as Logic, DRAM, or Flash memory devices. The process 100 further includes forming a first plasma from a first process gas. The first process gas may include hydrogen (H₂) and oxygen (O₂). The first plasma formed may be utilized to deposit an oxide layer that covers at least a portion of the film stack. The process 100 need not be limited to depositing an oxide layer that covers at least a portion of a film stack, and other embodiments are possible. For example, the process 100 may be utilized to grow an oxide layer, such as a gate oxide or tunnel oxide, on a surface of a silicon substrate such as during the formation of a transistor or flash memory device. In some embodiments, the process 100 may be utilized to form an oxide layer at room temperature, or about 25 degrees Celsius.

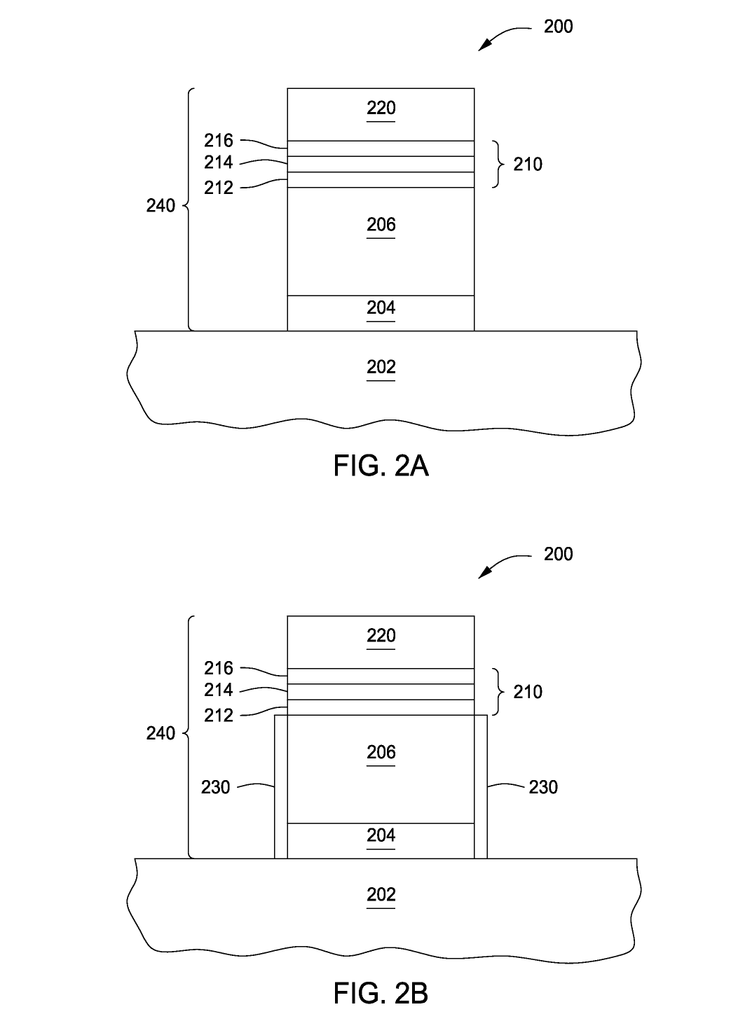

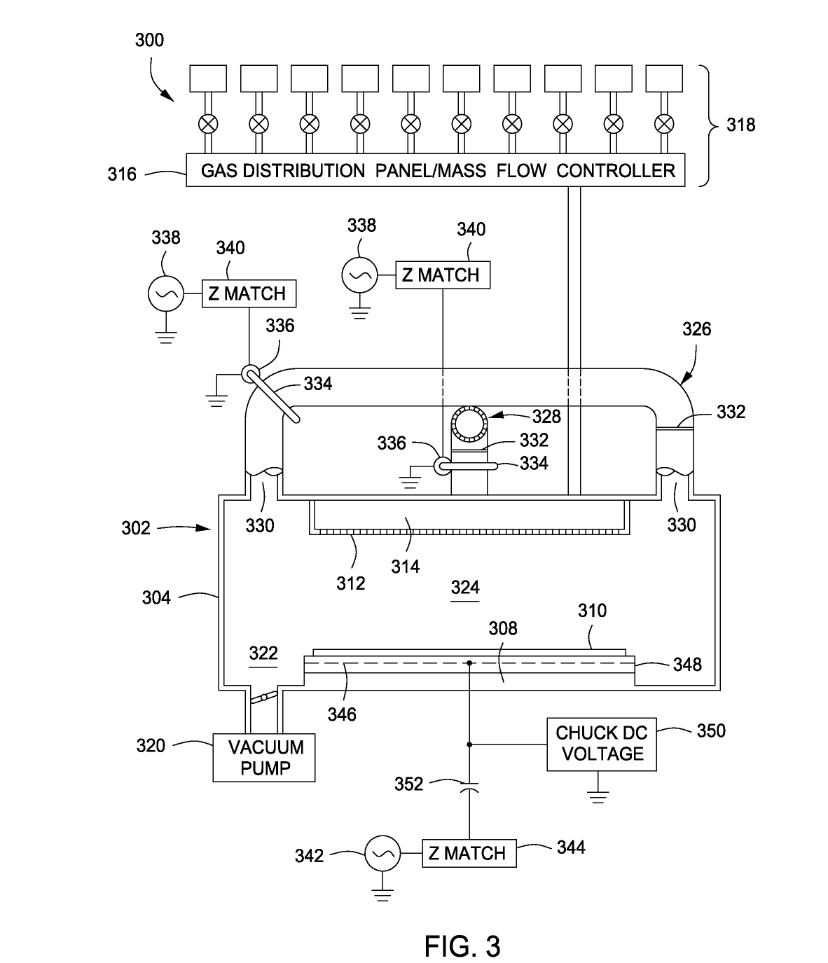

The process 100 is described herein with respect to the semiconductor structures depicted in FIGS. 2A-B, which respectively depict stages of fabrication of a semiconductor structure including a film stack formed over a semiconductor substrate. The process 100 may be performed in a toroidal source plasma immersion ion implantation reactor such as the plasma reactor depicted in FIG. 3. The toroidal source plasma reactor may be capable of generating higher plasma densities than conventional inductively coupled or capacitively coupled plasma reactors. Such high plasma density may facilitate a reduced growth temperature and improved growth rate of an oxide layer 230 discussed below. The reduced growth temperature may advantageously facilitate improved selectivity of the oxide layer 230 even at higher growth rates. Although only a toroidal source plasma reactor is described in the present application, it is contemplated that other suitable plasma reactors may be used to perform the inventive methods. Such plasma reactors include, but are not limited to, Decoupled Plasma Oxidation (DPO) reactors available from Applied Materials, Inc., of Santa Clara, Calif.

The process 100 begins at 110, where a substrate 202 is provided having a film stack 240 to be oxidized disposed thereupon, as shown in FIG. 2A. The substrate 202 may have various dimensions, such as 200 or 300 mm diameter wafers, as well as rectangular or square panels. The substrate 202 may comprise a material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, or the like.

The semiconductor device 200 may be completely or partially formed upon the substrate 202 and includes at least a film stack 240. In some embodiments, as shown in FIG. 1 at 112, the film stack 240 may be formed upon the substrate 202 and then provided to a suitable plasma process chamber for the oxidation process. For example, the film stack 240 may be fabricated in one or more process chambers coupled to a cluster tool that also has a plasma process chamber coupled thereto. One example of a suitable cluster tool is a Gate Stack CENTURA®, available from Applied Materials, Inc., of Santa Clara, Calif.

The film stack 240 may be any stack of materials including metal-containing and non-metal containing layers where the non-metal containing layers are to be selectively oxidized. The metal-containing layers may include electrically conductive ceramics partially comprising a metal, or purely comprise one or more metals. The metal-containing layers may include titanium nitride (TiN), tungsten silicon nitride (WSiₓN), tungsten nitride (WN), tantalum carbide (TaC), and tantalum nitride (TaN), titanium (Ti) and tungsten (W). Such a film stack may be part of a dynamic random access memory (DRAM) memory device. Because an oxidation process may cause undesired oxidation of the metal-containing layers, reducing desired properties such as conductivity, a selective oxidation process may be required. Such a selective process would preferentially oxidize at least some of the non-metal containing layers, but cause limited or no oxide layer to form on the metal-containing layers. Hence, the desired properties of the metal-containing layers may be preserved.

For example, in some embodiments, such as in DRAM memory devices, the film stack 240 may be any stack of materials to be oxidized where selective oxidation is desired. In some embodiments, the stack 240 includes a tunnel oxide layer 204, a floating gate layer 206, one or more electrically conductive barrier layers 212, 214, at least one metal layer 216 and a capping layer 220. The electrically conductive barrier layers 212, 214, and the metal layer 216 form a metal electrode 210. The one or more electrically conductive barrier layers 212, 214 may include titanium nitride (TiN), tungsten silicon nitride (WSiₓN), tungsten nitride (WN), tantalum carbide (TaC), and tantalum nitride (TaN). The at least one metal layer 216 may include titanium (Ti) and tungsten (W). In some embodiments, the electrically conductive barrier layers 212, 214 are TiN and WN, respectively. In some embodiments, the metal layer 216 is tungsten (W). The floating gate layer 206 comprises a conductive material, such as polysilicon (Si). The tunnel oxide layer 204 comprises an oxygen-containing material, such as silicon oxide (SiO₂), or the like. The capping layer 220 comprises an insulating material, such as silicon nitride (SiN).

Film stacks in other applications comprising both metal-containing layers and non metal-containing layers may be advantageously oxidized in accordance with the teachings provide herein, wherein an oxide layer may be selectively formed on portions of the gate stack, such as the side walls of the tunnel oxide layer 204, and floating gate layer 206, and wherein the metal-containing layers (for example, the electrically conductive barrier layers 212, 214, and the metal layer 216) remain free of an oxide layer, for example as illustrated in FIG. 2B. Such film stacks may illustratively include Charge Trap Flash (CTF) for Non-volatile Memory (NVM), or the like. Charge Trap Flash (CTF) for Non-volatile Memory (NVM) uses a SiO₂/SiN/Al₂O₃ gate stack with a metal electrode of tantalum nitride (TaN) or titanium nitride (TiN) that may also benefit from sidewall oxidation after gate etch.

Next, at 120, a first process gas comprising hydrogen (H₂) and oxygen (O₂) may be introduced into a plasma reactor, such as plasma reactor 300 described below in FIG. 3. In some embodiments, hydrogen (H₂) may be less than about 90 percent, or up to about 75 percent of the total amount of hydrogen (H₂) and oxygen (O₂) provided. In some embodiments, the hydrogen (H₂) may be about 50-80 percent of the total amount of oxygen (O₂) and hydrogen (H₂) provided (e.g., a flow rate ratio of hydrogen (H₂) to oxygen (O₂) about 1:1-4:1). The addition of hydrogen (H₂) to the oxygen (O₂) can increase the thickness of a silicon oxide film by up to about 30 percent, as compared to similar processes using oxygen (O₂) alone.

In some embodiments, the first process gas may be provided at total flow rate of between about 100-2000 sccm, or at about 150 sccm. For example, oxygen (O₂) and hydrogen (H₂) may be provided in a total flow rate of between about 100-2000 sccm, or at about 150 sccm, in the percentage ranges described above. In some embodiments, the inert gases may be provided as necessary to provide a total flow rate of between about 100-2000 sccm. In some embodiments, the inert gases may be provided as necessary to provide a process gas mixture having a content of about 50 percent or higher hydrogen (H₂). One or more Inert gases may also be provided to prevent recombination of the ionized oxygen and/or hydrogen. In some embodiments, the one or more inert gases may include argon (Ar), helium (He), krypton (Kr), neon (Ne), or the like. The addition or one or more inert gases to the process gas may facilitate higher oxidation rates. In one specific embodiment, oxygen (O₂) is provided at about 30 sccm, hydrogen (H₂) is provided at about 120 sccm, and argon (Ar) is provided at about 20 sccm. In some embodiments, the inert gas may be added to the first process gas sustain a plasma, such as a first plasma described below at 130, during the process 100. Further, the addition of an inert gas, for example Ar, to the first process gas comprising O₂ and H₂ may improve the quality of an oxide layer formed using the first process gas.

Next, at 130, a first plasma may be generated from the first process gas above at 120 to selectively form an oxide layer 230 on a portion of the film stack 240 (e.g., on non metal-containing layers of the film stack, such as the tunnel oxide layer 204 and the floating gate layer 206), as shown in FIG. 2B. The first plasma may be formed in a plasma reactor capable of generating plasma at high densities, for example, between about 10¹⁰ to about 10¹¹ ions/cm³, or greater than about 10¹⁰ ions/cm³. One such exemplary chamber is a toroidal source plasma ion immersion implantation reactor described below with respect to FIG. 3. In some embodiments, the portion may further include an exposed surface of the substrate 202, for example, adjacent to the film stack 240.

The first plasma may be formed, for example in a process chamber configured for processing 300 mm diameter substrates by applying a source power between about 500 to 2500 Watts at suitable frequency to form a plasma (for example, in the MHz or GHz range, or between about 11.3 to about 13.0 MHz, or about 11.3 MHz or greater. In some embodiments, the first plasma is formed at densities of between about 10¹⁰ to about 10¹¹ ions/cm³. The first plasma may be formed remotely, or optionally, pulsed during oxide formation.

The substrate 202 may be biased during formation of the oxide layer 230 to control the flux of ions to the surface of the film stack 240, and, in some embodiments, to control the thickness of the oxide layer formed. In some embodiments, a bias voltage is applied to the substrate 202 at between about 50 to about 100 Volts. In some embodiments, the substrate is not biased during formation of the oxide layer 230.

The first plasma may be formed in a low pressure process, thereby reducing the likelihood of contamination induced defects. For example, in some embodiments, the oxide layer 230 may be formed at a pressure of about 5 mTorr, or between about 5 to about 100 mTorr, or less than about 500 mTorr. In some embodiments, ion bombardment-induced defects that might occur at such low pressure levels may be limited or prevented by using a remote plasma source as described below with respect to FIG. 3 or, optionally, by pulsing the plasma source power.

The substrate 202 may be maintained at about room temperature (about 22.5 degrees Celsius), or between about 20 to about 25 degrees Celsius, or at a temperature of between about 20-100 degrees Celsius, or less than about 100 degrees Celsius. The low temperature of the process reduces the ion energy of the plasma constituents, thereby limiting diffusion of oxygen between the layers of the film stack 240 and, thereby reducing oxygen diffusion related defects, such as bird's beak.

In some embodiments, the oxide layer 230 may be grown at a rate of between about 7-50 Angstroms per minute, or at least about 25 Angstroms per minute. The oxide layer 230 may be formed to any suitable thickness. For example, in some embodiments, the oxide layer 230 may be formed to a thickness of between about 5 to about 100 Angstroms. The process may have any suitable duration to form the oxide layer to the desired thickness. In some embodiments, the duration may be between about 10 to about 40 seconds.

In some embodiments, the oxide layer 230 may be formed to a desired thickness by an iterative sequence of the first plasma and a second plasma as described below. In some embodiments, an iteration may comprises exposing the structure to the first plasma for a first period of time and exposing the structure 200 to the second plasma for a second period of time.

For example, at 140, a second process gas comprising hydrogen (H₂) may be introduced into a plasma reactor, such as the plasma reactor 300 described below in FIG. 3. In some embodiments, the second process gas may consist of hydrogen, may consist essentially of hydrogen, or may consist of hydrogen and an inert gas. For example, in some embodiments, hydrogen (H₂) may be about 100 percent, or up to about 90 percent of the total amount of second process gas provided. In some embodiments, the hydrogen (H₂) may be about 50-80 percent of the total amount of second process gas provided (e.g., a flow rate ratio of hydrogen (H₂) to other gases (i.e., inert gas or gases) about 1:1-4:1). In some embodiments, the second process gas further comprises at least one inert gas, such as argon (Ar) or helium (He).

In some embodiments, the second process gas may be provided at total flow rate of between about 100-2000 sccm, or at about 170 sccm. For example, hydrogen (H₂), or hydrogen (H₂) and an inert gas may be provided in a total flow rate of between about 100-2000 sccm, or at about 150 sccm. In some embodiments, the inert gases may be provided as necessary to provide a total flow rate of between about 100-2000 sccm. In some embodiments, the inert gases may be provided as necessary to provide a second process gas having a content of about 50 percent or higher hydrogen (H₂). In some embodiments, the one or more inert gases may include argon (Ar), helium (He), krypton (Kr), neon (Ne), or the like. In one specific embodiment, hydrogen (H₂) is provided at about 150 sccm, and argon (Ar) is provided at about 20 sccm.

At 150, a second plasma may be generated from the second process gas and provided to the semiconductor structure 200. The second plasma may be utilized to clean the surface of the substrate 202 and/or film stack 240 prior to formation of the oxide layer 230 using the first plasma at 130. Alternatively, the second plasma may be used to clean the surface of a partially grown oxide layer 230 prior to exposing the substrate 202 to the first plasma for an additional period of time. The second plasma may advantageously promote a high oxidation rate and/or faster growth rate of the oxide layer 230.

The second plasma may be formed in a plasma reactor capable of generating plasma at high densities, for example, between about 10¹⁰ to about 10¹¹ ions/cm³, or greater than about 10¹⁰ ions/cm³. One such exemplary chamber wherein the plasma is generated remotely is a toroidal source plasma ion immersion implantation reactor described below with respect to FIG. 3. The processing conditions, such as source power, bias power, pressure in the processing region, and temperature during processing are similar to those described above regarding the first plasma. Alternatively, in some embodiments, the pressure in a processing region of the reactor may be greater than in the first plasma, for example, between about 1 to about 10 Torr during formation and application of the second plasma. In some embodiments, the second process gas may have a flow rate of up to about 3 standard liters per minute (slm). In some embodiments, the second plasma is formed at plasma densities between about 10¹⁰ to about 10¹¹ ions/cm³, or greater than about 10¹⁰ ions/cm³.

Next, at 160, the structure 200 may be exposed to at least one of the first and second plasma in an iterative sequence. In one non-limiting example, one iteration of the iterative sequence may include exposing the structure 200 to the first plasma for a first period of time and exposing the structure 200 to the second plasma for a second period of time. In some embodiments, where it may be desired to clean the surface of the substrate 202 and/or film stack 240, the iterative sequence may begin by initially providing the second plasma. In embodiments, where the surface of the substrate 202 and/or film stack 240 is clean, the iterative sequence may begin by initially providing the first plasma. The iterative sequence may last for a total duration of between about 60-300 seconds, or until an oxide layer 230 of desired thickness is achieved. In some embodiments, the structure 200 may be exposed to the first plasma for a first period of time of between about 10-20 seconds. In some embodiments, the duration of the initial exposure of the structure 200 to the first plasma may be longer than subsequent exposures during subsequent iterations of the sequence. In some embodiments, the structure 200 may be exposed to the second plasma for a second period of time of about 15 seconds. In some embodiments, the duration of the initial exposure of the structure 200 to the second plasma may be longer than subsequent exposures during subsequent iterations of the sequence. For example, the duration of the initial exposure of the structure 200 to the second plasma may be longer than subsequent exposures because the surface of the substrate 202 and/or film stack 240 may have a high initial concentration of contaminants prior to growing the oxide layer 230.

Upon selectively forming the oxide layer 230 to a desired thickness on non-metal containing layers of the film stack 240 at 130 using the first plasma, or alternatively by an iterative sequence using the first and second plasmas, the process 100 ends. The substrate 202 may be subsequently further processed as necessary to complete the structures being fabricated thereon.

Further, and prior to performing the process 100 described above, a reactor utilized to perform the process 100, such as the reactor 300 described below, may be cleaned and/or seasoned. For example, the reactor may be purged to remove residues, such as process gases, byproducts, polymers or the like. Further, the reactor may be seasoned, for example, to deposit a seasoning layer on components of the reactor to prevent flaking or the like during processing. The cleaning and/or seasoning of the reactor may prevent contaminants, such as metal contaminants, including aluminum, aluminum containing materials, or other metals which may comprise reactor components, from reducing the quality of the oxide layer formed during the process 100 (e.g., becoming deposited in or on the oxide layer).

Embodiments of the present invention may be performed in toroidal source plasma ion immersion implantation reactor such as, but not limited to, the P3i reactor commercially available from Applied Materials, Inc., of Santa Clara, Calif. Such a suitable reactor and its method of operation are set forth in U.S. Pat. No. 7,166,524, assigned to the assignee of the invention, and which is incorporated herein by reference.

Referring to FIG. 3, a toroidal source plasma immersion ion implantation (“P3i”) reactor 300 of the type disclosed in the above-reference application has a cylindrical vacuum chamber 302 defined by a cylindrical side wall 304 and a disk-shaped ceiling 306. A substrate support pedestal 308 at the floor of the chamber supports a substrate 310 (e.g., substrate 202 with film stack 240 disposed thereon) to be processed. A gas distribution plate or showerhead 312 on the ceiling 306 receives process gas in its gas manifold 314 from a gas distribution panel 316 whose gas output can be any one of or mixtures of gases from one or more individual gas supplies 318. A vacuum pump 320 is coupled to a pumping annulus 322 defined between the substrate support pedestal 308 and the sidewall 304. A processing region 324 is defined between the substrate 310 and the gas distribution plate 312.

Pair of external reentrant conduits 326, 328 establishes reentrant toroidal paths for plasma currents passing through the processing region 324, the toroidal paths intersecting in the processing region 324. Each of the conduits 326, 328 has a pair of ends 330 coupled to opposite sides of the chamber. Each conduit 326, 328 is a hollow conductive tube. Each conduit 326, 328 has a D.C. insulation ring 332 preventing the formation of a closed loop conductive path between the two ends of the conduit.

An annular portion of each conduit 326, 328, is surrounded by an annular magnetic core 334. An excitation coil 336 surrounding the core 334 is coupled to an RF power source 338 through an impedance match device 340. The two RF power sources 338 coupled to respective ones of the cores 336 may be of two slightly different frequencies. The RF power coupled from the RF power generators 338 produces plasma ion currents in closed toroidal paths extending through the respective conduit 326, 328 and through the processing region 324. These ion currents oscillate at the frequency of the respective RF power source 338. Bias power is applied to the substrate support pedestal 308 by a bias power generator 342 through an impedance match circuit 344.

Plasma formation and subsequent oxide layer formation is performed by introducing a process gas, or mixture of process gases into the chamber 324 through the gas distribution plate 312 and applying sufficient source power from the generators 338 to the reentrant conduits 326, 328 to create toroidal plasma currents in the conduits and in the processing region 324. The plasma flux proximate the wafer surface is determined by the wafer bias voltage applied by the RF bias power generator 342. The plasma rate or flux (number of ions sampling the wafer surface per square cm per second) is determined by the plasma density, which is controlled by the level of RF power applied by the RF source power generators 338. The cumulative ion dose (ions/square cm) at the wafer 310 is determined by both the flux and the total time over which the flux is maintained.

If the wafer support pedestal 308 is an electrostatic chuck, then a buried electrode 346 is provided within an insulating plate 348 of the wafer support pedestal, and the buried electrode 346 is coupled to the bias power generator 342 through the impedance match circuit 344.

In operation, and for example, the selective formation of an oxide layer on the substrate 310 is achieved by placing the substrate 310 on the substrate support pedestal 308, introducing one or more process gases into the chamber 302 and striking a plasma from the process gases.

In operation, a plasma may be generated from the process gases within the reactor 300 to selectively form an oxide layer on the substrate 310. The plasma is formed in the processing region 324 by applying sufficient source power from the generators 338 to the reentrant conduits 326, 328 to create plasma ion currents in the conduits 326, 328 and in the processing region 324 in accordance with the process described above. In some embodiments, the wafer bias voltage delivered by the RF bias power generator 342 can be adjusted to control the flux of ions to the wafer surface, and possibly the thickness of the oxide layer formed. In some embodiments, no bias power is applied.

Thus, embodiments of processes for forming an oxide layer on a substrate, or on a film stack disposed thereon, have been provided herein. The processes advantageously provide selective formation of the oxide layer on non metal-containing layers of a film stack at reduced temperatures and formation times.

While the foregoing is directed to embodiments of the present invention, other and further embodiments of the invention may be devised without departing from the basic scope thereof.

What is claimed is:

1. A method of selectively forming an oxide layer on a semiconductor structure, comprising:
providing a substrate having one or more metal-containing layers and one or more non metal-containing layers to a substrate support in a plasma reactor;
introducing a first process gas into the plasma reactor, wherein the first process gas comprises hydrogen (H₂) and oxygen (O₂);
maintaining the structure at a temperature of less than about 100 degrees Celsius; and
generating a first plasma from the first process gas to selectively form an oxide layer on the one or more non metal-containing layers, wherein the first plasma has a density of greater than about 10¹⁰ ions/cm³.

2. The method of claim 1, wherein the one or more metal-containing layers and one or more non metal-containing layers are part of a film stack disposed on the substrate, and wherein the film stack further comprises a tunnel oxide layer, a floating gate layer, one or more electrically conductive barrier layers, and a capping layer.

3. The method of claim 2, wherein the oxide layer is selectively formed on a side wall of the tunnel oxide layer and the floating gate layer.

4. The method of claim 1, wherein the substrate comprises silicon and wherein the oxide layer comprises silicon and oxygen.

5. The method of claim 1, wherein a flow rate ratio of hydrogen (H₂) to oxygen (O₂) is between about 1:1 to about 4:1.

6. The method of claim 5, wherein a flow rate of hydrogen (H₂) is about 120 sccm.

7. The method of claim 5, wherein a flow rate of oxygen (O₂) is about 30 sccm.

8. The method of claim 1, further comprising:
introducing a second process gas into the plasma reactor, wherein the second process gas comprises hydrogen (H₂);
generating a second plasma from the second process gas, wherein the second plasma has a plasma density of greater than 10¹⁰ and
providing the second plasma to the structure.

9. The method of claim 8, wherein the first plasma and second plasma are provided to the structure in an iterative sequence.

10. The method of claim 9, wherein the duration of the iterative sequence is between about 60 to about 300 seconds.

11. The method of claim 9, wherein the first plasma is provided for a first period of time of between about 10 to about 20 seconds during each iteration.

12. The method of claim 9, wherein the second plasma is provided for a second period of time of at least about 15 seconds during each iteration.

13. The method of claim 9, wherein the second process gas further comprises an inert gas.

14. The method of claim 1, wherein the first process gas further comprises an inert gas.

15. The method of claim 1, wherein the first plasma is provided for between about 10 to about 40 seconds.

16. The method of claim 1, wherein the structure is maintained at a temperature of between about 20 to about 25 degrees Celsius.

17. The method of claim 1, wherein a bias voltage of between about 50 to about 100 Volts is applied to the substrate support.

18. The method of claim 1, wherein the processing region is maintained at a pressure of between about 5 to about 100 mTorr.

19. The method of claim 1, wherein a source power of up to 2500 Watts is used to generate the first plasma.

20. The method of claim 1, wherein in the oxide layer is formed to a thickness of between about 5 to about 100 Angstroms.
